(19) United States
(12) Patent Application Publication
(10) Pub. No.: US 2022/0336208 A1
(43) Pub. Date: Oct. 20, 2022

(54) WAFER SURFACE TREATMENT DEVICE

(71) Applicant: JOY ALLIED TECHNOLOGY INC., New Taipei City (TW)

(72) Inventor: TE-MING CHIANG, Hsinchu City (TW)

(21) Appl. No.: 17/858,095

(22) Filed: Jul. 6, 2022

Related U.S. Application Data
(62) Division of application No. 17/106,207, filed on Nov. 30, 2020.

(30) Foreign Application Priority Data
Dec. 10, 2019 (TW) 108145193

(51) Int. Cl. H01L 21/02; H01L 21/67; H01L 21/311

(52) U.S. Cl. CPC H01L 21/02049; H01L 21/67034; H01L 21/311; H01L 21/31116

(57) ABSTRACT

A wafer surface treatment device and a method thereof are disclosed. The wafer surface treatment device includes a main body internally defining a treatment space; a movable door provided on one side of the main body; a gas atomizer provided in the treatment space; a heater provided in the treatment space; and a control unit connected to the gas atomizer and the heater.

### CROSS-REFERENCE TO RELATED APPLICATION

This application is a divisional patent application of U.S. application Ser. No. 17/106,207 filed on Nov. 30, 2020, which claims priority to Taiwanese Patent Application No. 108145193 filed on Dec. 10, 2019, the entire contents both of which are hereby incorporated by reference for which priority is claimed under 35 U.S.C. § 121.

### BACKGROUND OF THE INVENTION

### 1. Field of the Invention

The present disclosure relates to a wafer surface treatment device, and in particular to a wafer surface treatment device that includes a gas atomizer and a heater. The present disclosure also relates to a wafer surface treatment method, and in particular to a wafer surface treatment method that is applied to the removal of a silicon dioxide layer from the surface of a wafer.

### 2. Description of the Related Art

The surface of a wafer is subjected to oxidization to grow a layer of silicon dioxide thereon. The removal of the silicon dioxide layer from the wafer surface is a key step in the process of wafer surface treatment. However, conventional wafer surface treatment devices and wafer surface treatment methods can only remove the silicon dioxide layer up to 100 Å in thickness. In the event the silicon dioxide layer grown on the wafer surface excesses 100 Å in thickness, portions of the silicon dioxide layer exceeded 100 Å would remain on the wafer surface and could not be removed by the conventional wafer surface treatment devices and methods. And, the silicon dioxide layer remained on the wafer surface would severely affect subsequent fabrication processes and the good yield of related products.

### BRIEF SUMMARY OF THE INVENTION

In view of the drawback in the prior art, an objective of the present disclosure is to provide an improved wafer surface treatment device and wafer surface treatment method.

To achieve at least the above objective, the wafer surface treatment device according to the present disclosure includes:

a main body internally defining a treatment space;

a movable door provided on one side of the main body;

a gas atomizer provided in the treatment space; and

a heater provided in the treatment space.

In an embodiment of the wafer surface treatment device, the heater is a heat-generating lamp.

In an embodiment, the wafer surface treatment device further includes a control unit connected to the gas atomizer and the heater.

To achieve at least the above objective, the wafer surface treatment method according to the present disclosure includes the following steps:

(A) placing a wafer in a treatment space of a wafer surface treatment device, and the wafer having a layer of silicon dioxide grown on a surface thereof; wherein the wafer surface treatment device includes:

a main body internally defining a treatment space;

a movable door provided on one side of the main body;

a gas atomizer provided in the treatment space; and

a heater provided in the treatment space;

(B) closing the movable door of the wafer surface treatment device;

(C) turning on the gas atomizer to spray atomized hydrogen fluoride gas into the treatment space;

(D) turning off the gas atomizer;

(E) turning on the heater to remove water from a surface of the wafer and remove moisture from the treatment space;

(F) tuning off the heater; and

(G) repeating the steps (C) to (F) a predetermined number of times.

According to an embodiment of the wafer surface treatment method, in the step (C), the gas atomizer is turned on for one minute.

According to an embodiment of the wafer surface treatment method, in the step (C), the atomized hydrogen fluoride gas sprayed into the treatment space has a concentration between 1% and 49%.

According to an embodiment of the wafer surface treatment method, the heater is a heat-generating lamp.

According to an embodiment of the wafer surface treatment method, in the step (E), the heater is turned on for three minutes.

According to an embodiment of the wafer surface treatment method, in the step (E), the heater is turned on to raise a temperature of the wafer surface to 80 to 95° C.

According to an embodiment of the wafer surface treatment method, the wafer surface treatment device further includes a control unit connected to the gas atomizer and the heater; and

wherein, in the step (G), the gas atomizer and the heater are sequentially turned on and turned off via the control unit to repeat the steps (C) to (F) the predetermined number of times.

The wafer surface treatment device and the wafer surface treatment method according to the present disclosure can remove the silicon dioxide layer that is grown on a wafer surface and reaches a thickness up to 200 to 20000 Å and accordingly, can fully fulfill the requirement for wafer surface treatment.

### BRIEF DESCRIPTION OF THE DRAWINGS

For the purpose of easy and clear description, the thickness or sizes of elements in the drawings might have been increased, omitted or schematically represented; and the dimensions of different elements in the drawings do not necessarily reflect the real dimensions thereof.

FIG. 1 is a schematic view of a wafer surface treatment device according to a first embodiment of the present disclosure.

FIG. 2 is a flowchart showing the steps included in a wafer surface treatment method according to a second embodiment of the present disclosure.

FIG. 3 is a schematic view of a wafer surface treatment device according to a third embodiment of the present disclosure.

FIG. 4 is a flowchart showing the steps included in a wafer surface treatment method according to a fourth embodiment of the present disclosure.

### DETAILED DESCRIPTION OF THE INVENTION

To facilitate understanding of the objects, characteristics and effects of this present disclosure, embodiments together with the attached drawings for the detailed description of the present disclosure are provided. It is noted the present disclosure can be implemented or applied in other embodiments, and many changes and modifications in the described embodiments can be carried out without departing from the spirit of the disclosure, and it is also understood that the preferred embodiments are only illustrative and not intended to limit the present disclosure in any way.

### First Embodiment: Wafer Surface Treatment Device

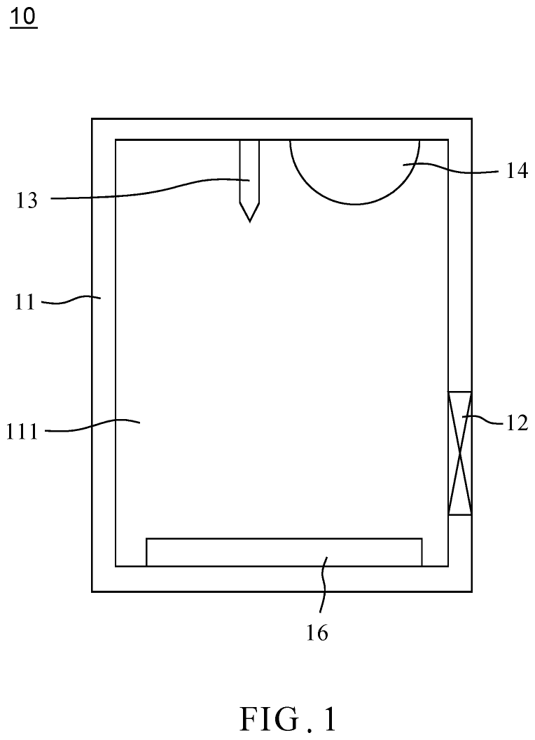

As shown in FIG. 1, a wafer surface treatment device 10 according to a first embodiment of the present disclosure includes a main body 11 that internally defines a treatment space 111; a movable door 12 being provided on one side of the main body 11; a gas atomizer 13 being provided in the treatment space 111; and a heater 14 being provided in the treatment space 111.

When a wafer 16 having a silicon dioxide layer grown on a surface thereof is to be treated, place the wafer 16 in the treatment space 111 of the wafer surface treatment device 10 and close the movable door 12 of the device 10. Then, turn on the gas atomizer 13 to spray atomized hydrogen fluoride (HF) gas into the treatment space 111 and wait for a predetermined length of time before turning off the gas atomizer 13. Thereafter, turn on the heater 14 in order to remove water from the surface of the wafer 16 and remove moisture from the treatment space 111. The heater 14 is turned off after a predetermined length of time. Finally, sequentially repeat turn on/off the gas atomizer 13 and turn on/off the heater 14 until the silicon dioxide layer on the surface of the wafer 16 is substantially removed.

In an embodiment of the present disclosure, the heater 14 is a heat-generating lamp capable of raising a temperature of the wafer surface to 80 to 95° C. However, it is understood the heat-generating lamp is only illustrative and non-restrictive. A person of ordinary skill in the art can use any other well-known heating means, so long as the water on the wafer surface and the moisture in the treatment space 111 can be sufficiently removed.

The conventional wafer surface treatment device includes the gas atomizer but not the heater; and the gas atomizer sprays atomized hydrogen fluoride gas into the treatment space to etch off the silicon dioxide layer on the wafer surface. When using the conventional wafer surface treatment method to remove the silicon dioxide layer that is grown on the wafer surface and reaches a thickness up to 100 Å, water produced in the reaction of the hydrogen fluoride gas with the silicon dioxide is carried away from the wafer surface by silicon fluoride formed in the same reaction. Therefore, water formed in the above chemical reaction would not have any significant adverse influence on the removal of the silicon dioxide layer. However, in the case the silicon dioxide layer grown on the wafer surface reaches a thickness up to 200 to 20000 Å, a part of the water produced in the reaction of the hydrogen fluoride gas with the silicon dioxide would enter into clearances formed on the wafer surface after the silicon dioxide layer is etched off by the hydrogen fluoride gas without being carried away from the wafer surface by the silicon fluoride formed in the reaction. The water trapped in the etched clearances prevents the hydrogen fluoride gas from further reacting with the silicon dioxide layer that is still left on the wafer surface. As a result, the remaining silicon dioxide layer could not be sufficiently removed from the wafer surface.

Compared to the conventional wafer surface treatment device, the wafer surface treatment device 10 of the present disclosure further includes a heater 14. After the sprayed hydrogen fluoride gas has reacted with the silicon dioxide on the wafer surface for a predetermined length of time, the heater 14 of the wafer surface treatment device 10 of the present disclosure is used to remove the water remained in the etched clearances on the wafer surface. When the water in the clearances is vaporized and dried, the procedure of spraying the atomized hydrogen fluoride gas into the treatment space 111 is repeated. The procedures of spraying hydrogen fluoride gas, vaporizing and drying water, spraying hydrogen fluoride gas, and vaporizing and drying water are repeated to ensure successive reaction of the hydrogen fluoride gas with the silicon dioxide layer on the wafer surface as well as sufficient removal of the silicon dioxide layer from the wafer surface. With this arrangement, the wafer surface treatment device 10 according to the present disclosure can be used to remove the silicon dioxide layer that is grown on the wafer surface and reaches a thickness up to 200 to 20000 Å.

### Second Embodiment: Wafer Surface Treatment Method

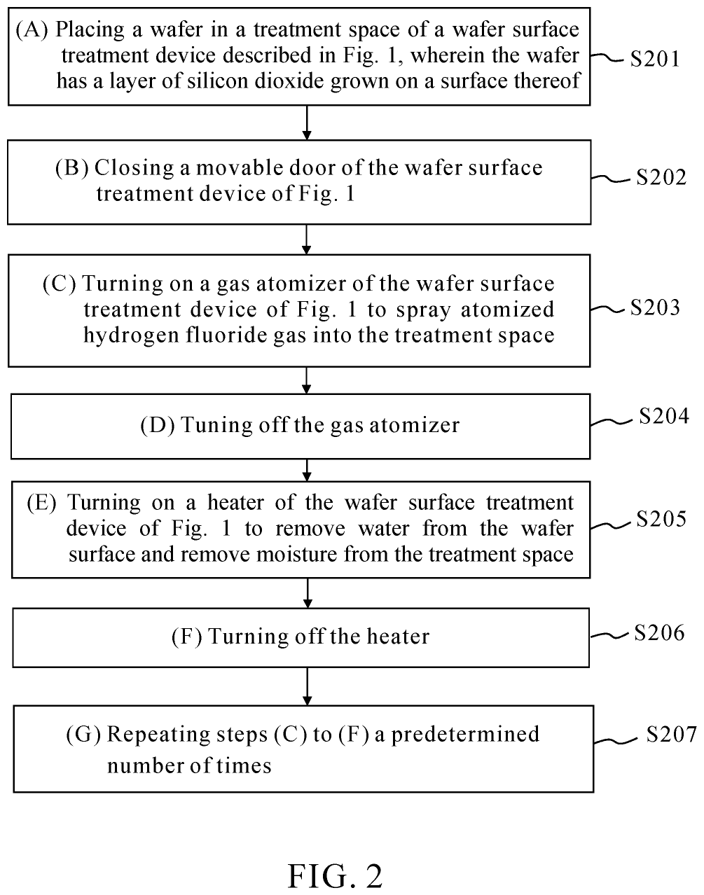

As shown in FIG. 2, a wafer surface treatment method according to a second embodiment of the present disclosure includes the steps of (A) placing a wafer in a treatment space of a wafer surface treatment device described in the first embodiment, wherein the wafer has a layer of silicon dioxide grown on a surface thereof (S201); (B) closing the movable door of the wafer surface treatment device of the first embodiment (S202); (C) turning on the gas atomizer of the wafer surface treatment device of the first embodiment to spray atomized hydrogen fluoride gas into the treatment space (S203); (D) tuning off the gas atomizer (S204); (E) turning on the heater of the wafer surface treatment device of the first embodiment to remove water from the wafer surface and remove moisture from the treatment space (S205); (F) turning off the heater (S206); and (G) repeating the steps (C) to (F) a predetermined number of times (S207).

According to an embodiment, in the step (C), the gas atomizer is turned on for one minute. However, it is understood the present disclosure is not particularly restricted to the above condition. That is, the gas atomizer can be turned on for other lengths of time, so long as the hydrogen fluoride gas can sufficiently react with the silicon dioxide layer on the wafer surface.

According to an embodiment, in the step (C), the atomized hydrogen fluoride gas sprayed into the treatment space has a concentration between 1% and 49%. However, it is understood the present disclosure is not particularly restricted thereto. A person of ordinary skill in the art may properly adjust the concentration of the hydrogen fluoride gas according to an actual condition in the treatment process.

According to an embodiment, in the step (E), the heater can be a heat-generating lamp, which is capable of raising a temperature of the wafer surface to 80 to 95° C. However, it is understood the present disclosure is not particularly restricted thereto. A person of ordinary skill in the art may use any other well-know heating means, so long as it can sufficiently remove any water from the wafer surface and any moisture from the treatment space.

In an embodiment, each time the steps (C) to (F) are repeated, a part of the silicon dioxide layer of 100 to 200 Å in thickness is removed. Preferably, the wafer is checked for its surface state when the steps (C) to (F) are completed once or after the steps (C) to (F) have been repeated a predetermined number of times. When a hydrophobic wafer surface is found, it means the silicon dioxide layer on the wafer surface has been exactly removed and the etching process on the wafer surface is completed.

Compared to the convention wafer surface treatment method, the wafer surface treatment method according to the second embodiment of the present disclosure further includes the heating step. That is, after the atomized hydrogen fluoride gas sprayed into the treatment space has reacted with the silicon dioxide layer on the wafer surface for a predetermined length of time, water left in the etched clearance can be further removed in the heating step. When the water in the etched clearance is vaporized and dried by the heater, the gas atomizer is turned on again to spray the atomized hydrogen fluoride gas into the treatment space one more time. By repeating the steps of spraying the hydrogen fluoride gas, vaporizing and drying the water, spraying the hydrogen fluoride gas, and vaporizing and drying the water, it is able to ensure the reaction of the hydrogen fluoride gas with the silicon dioxide layer on the wafer surface and the sufficient removal of the silicon dioxide layer from the wafer surface. With the wafer surface treatment method according to the second embodiment of the present disclosure, a silicon dioxide layer up to 200-20000 Å in thickness on the wafer surface can be removed.

### Third Embodiment: Wafer Surface Treatment Device with a Control Unit

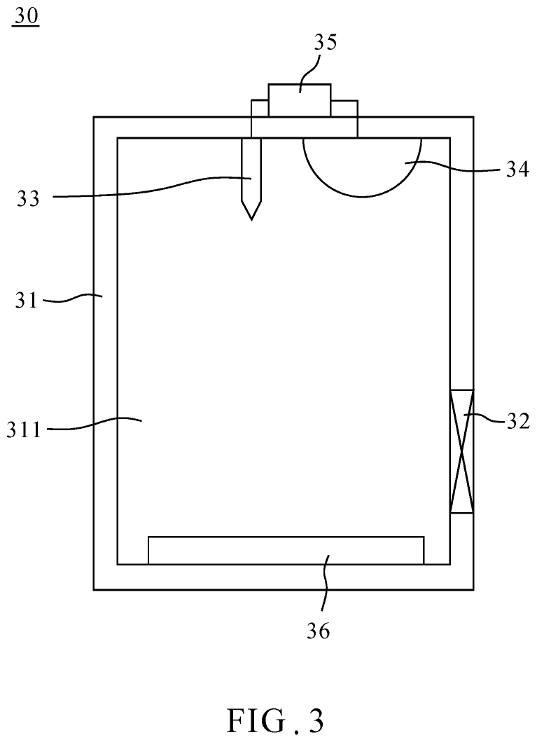

As shown in FIG. 3, a wafer surface treatment device 30 according to a third embodiment of the present disclosure includes a main body 31 that internally defines a treatment space 311; a movable door 32 being provided on one side of the main body 31; a gas atomizer 33 being provided in the treatment space 311; and a heater 34 being provided in the treatment space 311.

Compared to the first embodiment, the wafer surface treatment device 30 in the third embodiment further includes a control unit 35, which is connected to the gas atomizer 33 and the heater 34.

When a wafer 36 having a silicon dioxide layer grown on a surface thereof is to be treated, place the wafer 36 in the treatment space 311 of the wafer surface treatment device 30 and close the movable door 32 of the device 30. Then, turn on the gas atomizer 33 via the control unit 35 to spray atomized hydrogen fluoride (HF) gas into the treatment space 311 and wait for a predetermined length of time before turning off the gas atomizer 33 via the control unit 35. Thereafter, turn on the heater 34 via the control unit 35 in order to remove water from the surface of the wafer 36 and remove moisture from the treatment space 311. The heater 34 is turned off via the control unit 35 after a predetermined length of time. Finally, sequentially repeat turn on/off the gas atomizer 33 and turn on/off the heater 34 via the control unit 35 until the silicon dioxide layer on the surface of the wafer 36 is substantially removed.

Compared to the first embodiment, the wafer surface treatment device 30 with the control unit 35 in the third embodiment enables realization of automated wafer surface treatment process.

### Fourth Embodiment: Wafer Surface Treatment Method Applying a Control Unit

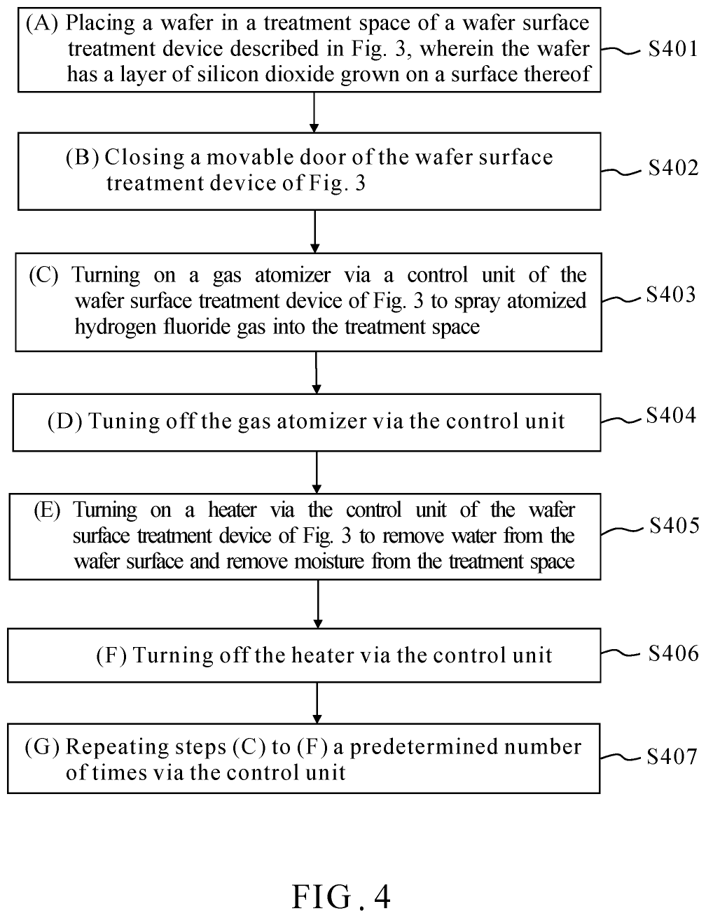

As shown in FIG. 4, a wafer surface treatment method according to a fourth embodiment of the present disclosure includes the steps of (A) placing a wafer in a treatment space of a wafer surface treatment device described in the third embodiment, wherein the wafer has a layer of silicon dioxide grown on a surface thereof (S401); (B) closing the movable door of the wafer surface treatment device of the third embodiment (S402); (C) turning on the gas atomizer via the control unit of the wafer surface treatment device of the third embodiment to spray atomized hydrogen fluoride gas into the treatment space (S403); (D) tuning off the gas atomizer via the control unit (S404); (E) turning on the heater via the control unit of the wafer surface treatment device of the third embodiment to remove water from the wafer surface and remove moisture from the treatment space (S405); (F) turning off the heater via the control unit (S406); and (G) repeating steps (C) to (F) a predetermined number of times via the control unit (S407).

Compared to the second embodiment, the wafer surface treatment method according to the fourth embodiment of the present disclosure further applies a control unit for sequentially turning on/off the gas atomizer and turning on/off the heater to repeat the steps (C) to (F) a predetermined number of times, enabling the realization of automated wafer surface treatment process.

In summary, the wafer surface treatment device and method thereof according to the present disclosure can be used to remove the silicon dioxide layer that is grown on the wafer surface and reaches a thickness up to 200 to 20000 Å. Further, in the preferred embodiments of the present disclosure, the wafer surface treatment device and method thereof can realize automated wafer surface treatment process.

While the present disclosure has been described by means of specific embodiments, numerous modifications and variations could be made thereto by those skilled in the art without departing from the scope and spirit of the present disclosure set forth in the claims.

What is claimed is:

1. A wafer surface treatment device, comprising:
a main body internally defining a treatment space;
a movable door provided on one side of the main body;
a gas atomizer provided in the treatment space;
a heater provided in the treatment space; and
a control unit connected to the gas atomizer and the heater and adapted for controlling:
(1) the turning on of the gas atomizer to spray atomized hydrogen fluoride gas into the treatment space;
(2) the turning off of the gas atomizer;
(3) the turning on of the heater to remove water from a surface of a wafer placed in the treatment space and to remove moisture from the treatment space;
(4) the turning off of the heater; and
(5) the repeated performing of the above items (1) to (4) a predetermined number of times.

2. The wafer surface treatment device according to claim 1, wherein the heater is a heat-generating lamp.
